(19) United States
(12) Patent Application Publication
(10) Pub. No.: US 2003/0091131 A1
(43) Pub. Date: May 15, 2003

(54) Pre-processor

(76) Inventor: Christopher Lloyd, Manchester (GB)

Correspondence Address: Nixon & Vanderhye, 8th Floor, 1100 North Glebe Road, Arlington, VA, 22201-4714, US

(21) Appl. No.: 10/181,978

(22) PCT Filed: Jan. 24, 2001
(86) PCT No.: PCT/GB01/00259

(30) Foreign Application Priority Data
Jan. 24, 2000 (GB) 0001491.0

(51) Int. Cl. H03D 1/00; H04L 27/06

(52) U.S. Cl. 375/343

(57) ABSTRACT

A method of pre-processing a signal comprising a series of temporally separated events, the method comprising modifying the temporal separation of the events prior to correlation of the signal.

The present invention relates to a means and apparatus for pre-processing a signal prior to correlation of that signal.

The elapsed time between pulses in a pulse stream provides useful information in many applications, for example fluorescence measurement. There are a number of ways in which this elapsed time may be analysed, such as auto-correlation of the pulse stream, cross-correlation of the pulse stream with some other signal, or Fourier transformation of the pulse stream. Each of these methods provides a phase independent measurement of frequency. These methods, and any other methods which provide a phase independent measurement of frequency may be generically grouped together under the term ‘correlation’. A correlator may be implemented in hardware, or may be implemented as software algorithms.

The sampling rate, or band width, of a given correlator is limited by the number of calculations that it is capable of performing per second. Where very fast data is to be measured, the data rate may exceed the sampling rate of the correlator and this will lead to a failure of the correlator. To overcome this problem it is known to transfer the very fast data to a memory buffer, and then subsequently correlate the stored data at a slower rate, once the data has been stored. For example, if a pulse stream of one minute duration is to be correlated, a resolution of 1 GHz will require a memory store of 6×10¹⁰ compartments, and assuming a processing bandwidth of 10 MHz, the analysis of the one minute duration pulse stream will take 1000 seconds. This method can only be used for a pulse stream of limited duration, and cannot be used to provide real time correlation.

It is an object of the present invention to overcome or mitigate the above disadvantage.

According to a first aspect of the invention there is provided a method of pre-processing a signal comprising a series of temporally separated events, the method comprising modifying the temporal separation of the events prior to correlation of the signal.

Preferably, the temporal separation between consecutive events is monitored, and if the temporal separation exceeds a predetermined maximum value, the temporal separation is substituted with a predetermined lesser value.

Preferably, predetermined lesser value is the predetermined maximum value.

Preferably, the predetermined maximum value corresponds to the maximum temporal separation that will provide a signal when the signal is correlated.

According to a second aspect of the invention there is provided a preprocessing means for pre-processing a signal comprising a series of temporally separated events, the pre-processing means being arranged to modify the temporal separation of the events prior to correlation of the signal.

Preferably, the pre-processing means comprises a timing device which monitors the temporal separation between consecutive events, and where the temporal separation exceeds a predetermined maximum value, changes the temporal separation of the consecutive events to a predetermined lesser value.

Preferably, the pre-processing means further comprises a pulse generator which generates a series of temporally separated pulses in accordance with temporal separation values output from the timing device.

Preferably, a buffer is located between the timing device and the pulse generator.

Preferably, the buffer comprises a pair of buffers arranged such that temporal separation values may be written to a first buffer from the timing device whilst temporal separation values are simultaneously transferred from a second buffer to the pulse generator.

Suitably, the method according to the first aspect of the invention comprises converting the temporal separation of the events into a non-linear form.

Preferably, the non-linear form is arranged to represent progressively greater temporal separations with temporal separations that increase at a lesser rate.

Suitably, the temporal separations are converted to the non-linear form in accordance with a predetermined sequence.

Preferably, the predetermined sequence is a geometric or substantially geometric sequence.

Suitably, the conversion to the non-linear form is arranged such that temporal separations of interest are given high resolution and temporal separations that are not of interest are given low resolution.

A pre-processing means according to the second aspect of the invention, wherein the pre-processing means further comprises a timing device which monitors the temporal separation between consecutive events, and converts the temporal separation of the events into a non-linear form.

Preferably, the pre-processing means further comprises a pulse generator which generates a series of temporally separated pulses in accordance with temporal separation values output from the timing device.

Preferably, a buffer is located between the timing device and the pulse generator.

Preferably, the buffer comprises a pair of buffers arranged such that temporal separation values may be written to a first buffer from the timing device whilst temporal separation values are simultaneously transferred from a second buffer to the pulse generator.

The first and second aspects of the invention may be used to increase the bandwidth of a correlator. Alternatively, the first and second aspects of the invention may be used to increase the temporal resolution of a correlator without altering the bandwidth.

The first aspect of the invention may be used in a communications system, a receiver being arranged to separate a data signal and a test signal, the test signal being correlated with a stored test signal, and the resulting correlation output being used to adjust gain of a data signal amplifier.

The second aspect of the invention may be used in a communications system, a receiver being arranged to separate a data signal and a test signal, the test signal being correlated with a stored test signal, and the resulting correlation output being used to adjust gain of a data signal amplifier.

According to a third aspect of the invention there is provided a method of preprocessing a signal comprising a series of temporally separated events, the method comprising converting the series of temporally separated events into a series of numbers, each number representing the temporal separation of two consecutive events.

Preferably, the method further comprises writing the numbers directly into channels of a correlator.

Suitably, the numbers are represented in binary and the numbers are converted to an alternative representation using a logical NOT function.

The third aspect of the invention may be combined with the first aspect of the invention.

According to a fourth aspect of the invention there is provided a preprocessing means for pre-processing a signal comprising a series of temporally separated events, comprising means for converting the series of temporally separated events into a set of numbers, each number representing the temporal separation of two consecutive events,.

Preferably, the pre-processing apparatus further comprises means for writing the numbers directly into channels of a correlator.

Suitably, the numbers are represented in binary and the numbers are converted to an alternative representation using a logical NOT function.

The fourth aspect of the invention may be combined with the second aspect of the invention.

According to a fifth aspect of the invention there is provided a method of detecting and representing a series of temporally separated events, the method comprising detecting the events using two detectors, and representing the series of events using a representation having two identifiers, a first identifier indicating whether events were detected simultaneously by the first and second detectors, and a second identifier indicating the time elapsed following a preceding event.

The fifth aspect of the invention may be considered to be pre-processing of a signal, in the sense that the signal provided by the fifth aspect of the invention is not simply a series of linearly separated events.

Suitably, outputs from the two detectors are connected by a logical AND function, and the first identifier is determined using output from the logical AND function.

Suitably, the outputs from the two detectors are connected together to provide a logical OR function, and the second identifier is determined using output from the logical OR function.

Preferably, the events are detected using more than two detectors, and the first identifier is arranged to indicate how many events were detected simultaneously by the more than two detectors.

Preferably, the number of detectors is chosen from the series 2ⁿ, where n is an integer.

Preferably, outputs from selected pairs of detectors are connected using logical AND functions.

Suitably, a router is arranged to direct a second identifier to one of a set of correlators, in accordance with the first identifier.

Alternatively, a router is arranged to direct a second identifier to a channel of a single correlator having interleaved channels, in accordance with the first identifier.

Suitably, the representation is converted to a representation having a single identifier, by dividing the second identifier by a factor corresponding to the number of detectors, and generating multiple copies of the first identifier when the first identifier indicates that more than one event was detected simultaneously by the detectors, the number of copies corresponding to the number of simultaneous events.

According to a sixth aspect of the invention there is provided an apparatus for detecting and representing a series of temporally separated events, the apparatus comprising two detectors for detecting events, and means for representing the series of events using a representation having two identifiers, a first identifier indicating whether events were detected simultaneously by the first and second detectors, and a second identifier indicating the time elapsed since a preceding event.

Suitably, outputs from the two detectors are connected by a logical AND function, and the first identifier is determined using output from the logical AND function.

Suitably, the outputs from the two detectors are connected together to provide a logical OR function, and the second identifier is determined using output from the logical OR function.

Suitably, the apparatus comprises more than two detectors, and the first identifier is arranged to indicate how many events were detected simultaneously by the more than two detectors.

Preferably, the number of detectors is chosen from the series 2ⁿ, where n is an integer.

Preferably, outputs from selected pairs of detectors are connected using logical AND functions.

Preferably, a router is arranged to direct a second identifier to one of a set of correlators, in accordance with the first identifier.

Alternatively, a router is arranged to direct a second identifier to a channel of a single correlator having interleaved channels, in accordance with the first identifier.

Suitably, the apparatus further comprises means for converting the representation to a representation having a single identifier, by dividing the second identifier by a factor corresponding to the number of detectors, and generating multiple copies of the first identifier when the first identifier indicates that more than one event was detected simultaneously by the detectors, the number of copies corresponding to the number of simultaneous events.

The term correlator means is intended to include any hardware or software which provides a phase independent measurement of frequency, and in particular is intended to include auto-correlation means, cross-correlation means and Fourier transformation means.

Specific embodiments of the invention will now be described with reference to the accompanying figures in which:

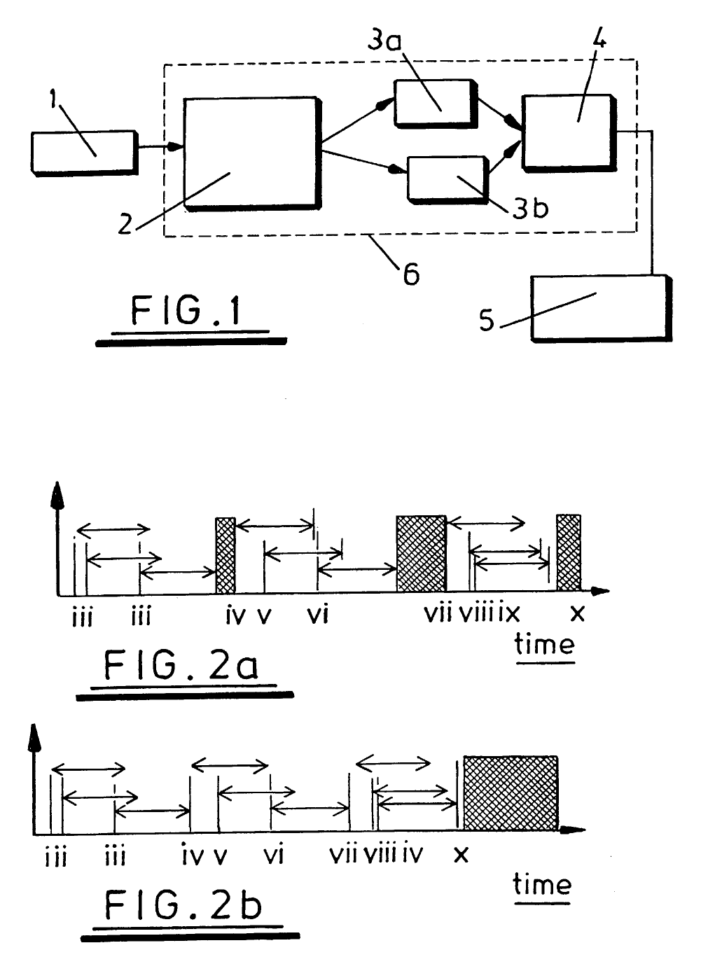

FIG. 1 is a schematic diagram of a correlator according to a first aspect of the invention,

FIG. 2 is a schematic representation of the operation of first aspect of the invention,

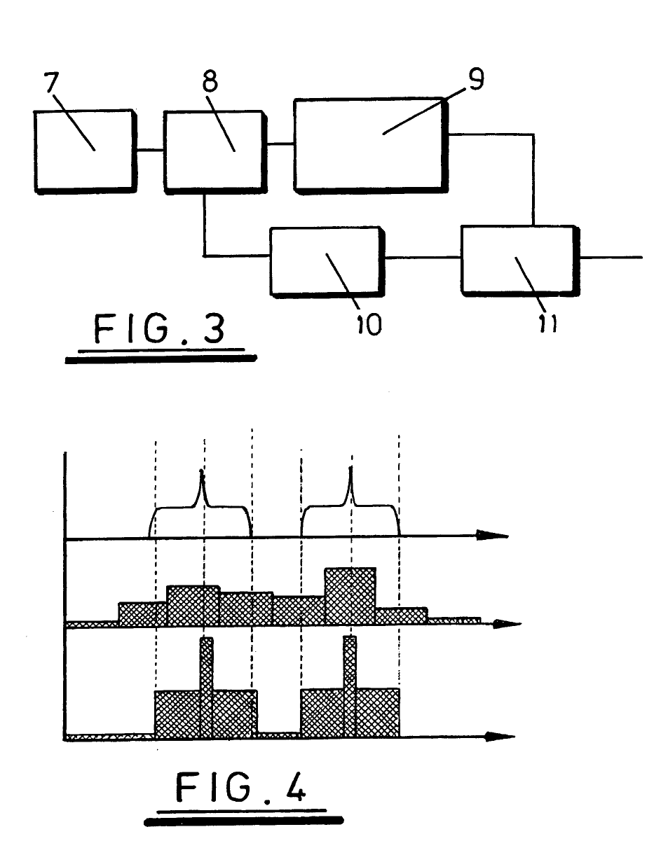

FIG. 3 is a schematic diagram of a communication apparatus utilising the first aspect of the invention,

FIG. 4 is a schematic diagram representing operation of the first aspect of the invention,

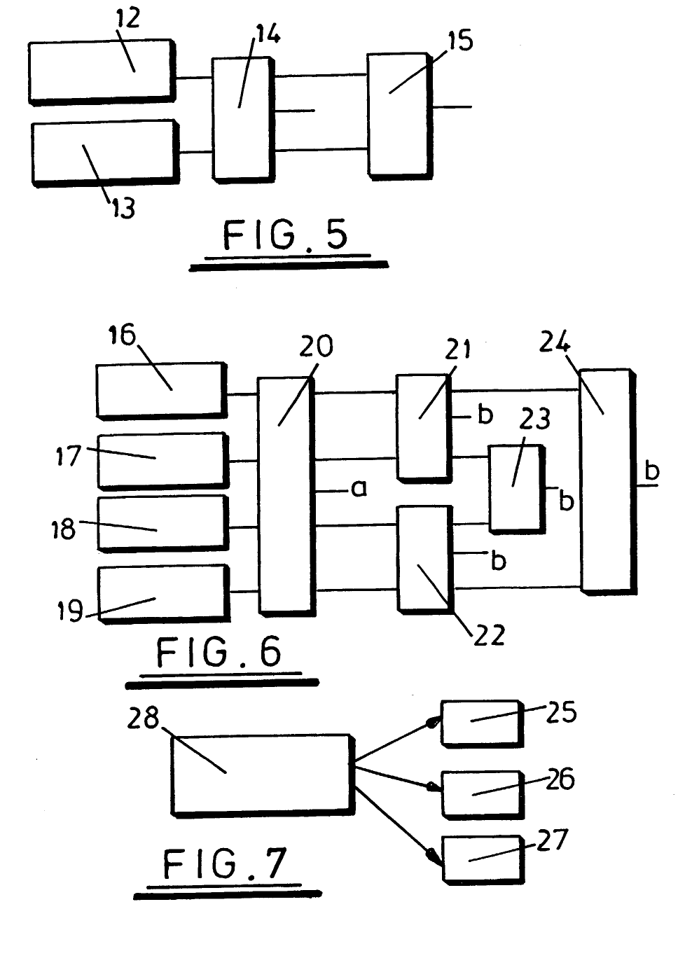

FIG. 5 is a schematic diagram of a detection circuit according to a third aspect of the invention;

FIG. 6 is a schematic diagram of a second detection circuit according to the third aspect of the invention; and

FIG. 7 is a schematic diagram illustrating utilisation of the fifth aspect of the invention.

Referring to FIG. 1, a pulse stream is detected at a detector 1, and the time elapsed between pulses is determined by a timing device 2. The timing device 2 outputs a series of numbers which correspond to the temporal separation between detected pulses, and these numbers are output to one of two buffers 3a, 3b. Data is read from one of the buffers, for example buffer 3a, and is transferred to a pulse generator 4. The pulse generator 4 generates a pulse stream in accordance with the numbers input from the buffer 3a. The pulse stream is transferred to a correlator 5. The timing device 2, buffers 3a, 3b, and pulse generator 4 may be collectively considered as a preprocessing circuit 6 for the correlator 5.

The invention is embodied in the operation of the pre-processing circuit, and in particular in the operation of the timing device 2. Whenever the elapsed time between successive pulses is determined by the timing device 2 to be longer than a predetermined maximum, the output number which represents the elapsed time is replaced by the number which represents the predetermined maximum time. The effect of this substitution is illustrated in FIGS. 2a and 2b. FIG. 2a represents a pulse stream incident at the timing device 2. Assuming that the correlator 5 has a sampling time of “t”, and that the correlator 5 is composed of N channels, then the correlation of the pulse stream will include a maximum event spacing of Nt. For example, if the sampling time of the correlator is 25 ns, and the correlator is composed of 256 channels, then the maximum event spacing is 6.4 μs.

Where successive pulses are separated by an elapsed time greater than Nt, the correlation will not reflect the elapsed time (in other words those two pulses will not be correlated with one another). This is illustrated in FIG. 2a. In FIG. 2a, the maximum event separation is represented by the horizontal arrows. Thus, the event indicated by the vertical line labelled ‘i’ and the event indicated by the vertical line labelled ‘ii’ will provide a correlation signal related to their temporal separation. Similarly, the event ‘i’ and the event ‘iii’ will provide a correlation signal related to their temporal separation, and so on. However, event ‘iii’ and event ‘iv’ are separated by a time greater than the maximum event spacing, and therefore will not provide a correlation signal. The shaded areas of FIG. 2 represent time during which there are no events which may contribute to the correlation signal

The timing device 2 removes the gaps represented by the grey boxes in FIG. 2a by limiting to Nt the maximum measured value of the elapsed time. Because these gaps did not contain any events that would contribute to the correlation signal, no information was lost from the signal when the gaps were removed, and the correlation provided by the correlator 5 is unchanged. The effect of the timing device 2 is illustrated in FIG. 2b. The grey box in FIG. 2b represents the time which has been “saved” by the timing device 2. Thus, in the illustrated example, a correlation of the events ‘i’ to ‘x’ will be carried out approximately 20% quicker.

Where the invention is applied to sparse data, the time saving provided by the invention is much greater than the 20% saving illustrated in FIG. 2. The invention effectively increases the bandwidth of a correlator.

An application of the invention is illustrated in FIG. 3, which shows schematically a communications receiver. The receiver is intended to decode a signal which comprises a correlation of a data signal and a test signal. The receiver comprises a detector 7, a separating means 8 for separating the test signal and the data signal, and a pre-processing circuit and correlator (collectively labelled 9) as described in relation to FIG. 1. The receiver further comprises a delay circuit 10 and a programmable gain filter/amplifier 11.

In use, a signal detected by the detector 7 is separated by the separator 8 into a test signal and a data signal. The test signal is passed to the pre-processing circuit and correlator 9, which correlates the received test signal with a test signal stored at the receiver. The frequency components indicated by the correlation are indicative of the transfer function of the medium through which the test signal has passed. This information is passed to the programmable gain filter/amplifier 11, and the gain of the filter/amplifier 11 is adjusted to take account of the transfer function. The delay circuit 10 is used to synchronise the arrival of the data signal at the filter/amplifier 11 so that the data signal is filtered or amplified in accordance with the transfer function which it experienced on passage through the medium. The receiver thus acts as an adaptive filter almost in real time. The correlator according to the invention is of importance because it is the correlator that allows the receiver to act continuously and almost in real time.

The receiver illustrated in FIG. 3 is advantageous because it provides for lower error in data communications, and thus allows transmission over longer distances or reduced power transmission. The receiver may be of particular use in mobile telecommunications applications.

As described above, the invention allows a correlator to process data at a greater rate than would otherwise be possible. It will be apparent that the invention may alternatively allow a correlator to process data at an unchanged rate but with a greater resolution. For example, a data stream comprising 1×10⁵ events per second (a typical data stream for light scattering experiments), this will have a mean event spacing of 10 μs. A typical correlator operating in single bit mode will have a sampling rate of the order of 10 ns, which, assuming that the correlator comprises 100 linearly spaced channels, will give a maximum event spacing of 1 μs. The invention will therefore ‘save’ of the order of 9 μs per event. This saving allows the sampling rate of the timing device to be set at 1 ns, and the correlator may then carry out a correlation of the data with a resolution improved by a factor of 10, since the data has been truncated to a tenth of its length. Use of the invention in this manner provides an increase of resolution without any loss of data. The invention allows a 100 channel 100 MHz correlator to operate continuously without data loss at frequencies of the order of 1 GHz.

In the general case, if the sampling period of the correlator is t, and the proportion of ‘saved’ time is u, then the resolution of a correlation may be improved to t/u using the invention. In order to do this, the buffers used by the invention should be sufficiently large that a mean event separation period may be assumed.

An alternative manner in which time may be ‘saved’ is by converting elapsed time periods into a nonlinear representation. For example, an interval of 1 μs may represent 1 μs, an interval of 2 μs represent 2 to 4 μs, an interval of 3 μs represent 5 to 8 μs, and an interval of 4 μs represent 9 to 16 μs, etc. This allows the correlator to process data more rapidly than if a linear representation of the elapsed time were used.

Referring to FIG. 1, the event separation information is converted to a nonlinear representation by the timing device 2, and is then transferred to one of the two buffers 3a, 3b. The event separation is output from one of the two buffers 3a, 3b to the pulse generator 4, which generates a pulse sequence. The pulse sequence provides input for the correlator 5 in the usual way, with the important distinction that this pulse sequence is a nonlinear representation of the pulse sequence that was detected by the detector 1.

Use of the nonlinear representation is advantageous because it reduces the average delay between pulses so that the correlation of the pulse sequence may be carried out more quickly. The nonlinear representation provides the greatest time saving for sparse data, where pulses are commonly separated by long time periods.

Although the use of a nonlinear representation has been described in terms of a geometric series, it will be understood that any nonlinear representation may be used.

The use of the nonlinear representation in effect provides a dilation of the correlator. The effective dilation of the correlator is provided without alteration of the channels of the correlator itself. The effect of the nonlinear representation may be removed from the correlation during analysis, using well known techniques which are currently used to remove dilation from a correlation.

The nonlinear representation of the pulse stream may be arranged to decrease in resolution and increase in resolution in a predetermined manner in order to increase correlator resolution at time intervals of interest and reduce correlator resolution at time intervals of no interest. An example of such variation of resolution is illustrated in FIG. 4, which comprises three output traces. The uppermost output trace of FIG. 4 is the correlation of a complex signal by an ideal correlator, the middle trace is the correlation of the complex signal by a conventional 8 channel linear correlator, and the lower trace is the correlation of the complex signal by an 8 channel correlator with resolution increasing and decreasing in a predetermined manner. This aspect of the invention is particularly advantageous because it allows the resolution of a correlator to be tailored to a specific application. For example, the resolution may be increased at points at and around a peak or trough of a signal, and may be decreased at points of negligible interest. It will be understood by those skilled in the art that the resolution of the correlator may not be increased beyond the resolution with which events were detected.

The apparatus shown in FIG. 1 generates a reformed series of pulses, following processing of the pulse series by the timing device 2. The processing reduces the separation of at least some of the pulses comprising the series, thereby reducing the time required to carry out a correlation.

The time required to carry out a correlation may be further reduced if, instead of reforming a pulse series prior to correlation as described above, a representation of the time between pulses is instead transferred directly to shift registers of a correlator. The resulting correlation will contain the same information that would have been provided if a conventional correlation had been carried out, although the information will be represented in a different format. The correlation may be converted into a conventional correlation. Transferring the time between pulses directly to the correlator is advantageous because it avoids filling a series of correlator channels with zeros when two events are widely separated. Instead, a number representative of an elapsed time is transferred into each channel. This allows a pulse stream to be correlated using a smaller number of correlator channels, and thus reduces the time required to carry out the correlation.

Where data is represented in binary, a logical NOT function may be applied to the data thereby converting the data into a form of ‘inverse’. The logical operation may be represented mathematically as |n-255|. For a correlator having 255 channels, a delay of 255 will be represented as 0, while a delay of 0 will be represented as 255. The ‘inverse’ representation is advantageous because the correlation obtained using that representation is close to that which would have been obtained using a conventional correlation.

A pulse stream may be represented using data having two identifiers, the first identifier representing the time between pulses, and the second identifier representing the number of pulses occurring within a single time interval. In other words, if a time interval were defined as 10 ns, then three pulses detected at 41 ns, 47 ns and 49 ns, would be represented as ‘40-50 ns, 3 pulses’.

Data having two identifiers may be represented in binary. For example, a signal (001,0), (010,1), (001,0), (010,0) represents a single pulse occurring during a first time period, two pulses occurring after one time period has elapsed (both pulses occurring during a second time period), a single pulse occurring during a first time period, and a single pulse occurring after one time period has elapsed (the single pulse occurring during a second time period). In this example, the maximum number of photons that can be represented for a single time period is two.

FIG. 5 shows a circuit which may be used to generate a data stream having two separate identifiers. The circuit comprises a pair of detectors 12, 13, a logical OR function 14 and a logical AND function 15. The logical OR function 14 provides an output whenever a pulse occurs at either detector 12, 13. The logical AND function 15 provides an output when pulses occur simultaneously at both detectors 12, 13.

In order to maximise the bandwidth of the circuit, the logical OR function 14 is not provided by a logic gate, but is instead provided by a direct connection of the outputs of the detectors 12, 13. The logical AND function 15 is provided by any suitable circuit (many suitable circuits are commercially available).

The circuit shown in FIG. 5 is advantageous when compared to the circuit shown in FIG. 1 because it can provide more information regarding a stream of pulses. In particular, the circuit of FIG. 1 is limited by the time required to convert an elapsed time interval into a voltage each time an event is detected. The circuit of FIG. 5 must also carry out the same conversion and therefore cannot resolve successive events with an accuracy greater than that provided by the circuit of FIG. 1. However, the circuit of FIG. 5 may represent two events detected simultaneously, via a single additional bit representative of the output of the logical AND function. The provision of this extra bit does not incur a significant time penalty, and the circuit of FIG. 5 thus provides more information within a given conversion time than is provided by the circuit of FIG. 1.

Because the circuit of FIG. 1 may not represent simultaneous events, a frequency distribution, for example a Poisson distribution, must be assumed during analysis of a correlation obtained using the circuit of FIG. 1. In contrast to this, the circuit of FIG. 5 allows the detection of simultaneous photons, provided that each photon is incident upon a separate detector 12, 13. This extra information obviates the need for a photon distribution to be estimated.

The circuit shown in FIG. 5 may be adapted to accommodate more than two detectors, and will remain relatively simple provided that the number of detectors is taken from the geometric series: 2, 4, 8, 16, 32, etc. The circuit becomes complicated for numbers of detectors other than those in the geometric series.

FIG. 6 shows a second circuit which generates a data stream having two separate identifiers. The circuit comprises four detectors 16-19, a logical OR function 20, and four logical AND functions 21-24. The logical OR function 20 provides an output each time a pulse is detected at any of the detectors 16-19. An output from one of the logical AND functions 21-24 indicates that at least two pulses have been detected simultaneously at at least two different detectors. It will be noted that there is no logical AND function connecting detectors 16 and 18, or connecting detectors 17 and 19. The fact that only a subset of the possible combinations of pairs of detectors are connected to logical AND functions may be corrected for following correlation by multiplying by a suitable factor.

Outputs from each of the logical AND functions 21-24 are connected together to a logical gate with four inputs (not shown), which provides an output if pulses occur simultaneously at all four of the detectors 16-19.

The circuit is capable of distinguishing a single pulse, two to three simultaneous pulses, and four simultaneous pulses. The circuit is not capable of distinguishing the difference between two simultaneous pulses and three simultaneous pulses.

A binary representation may be used to represent the pulses detected using the circuit of FIG. 6, for example (001,00), (001,01), (001,10) may represent respectively one pulse occurring within a single sample time, two or three pulses occurring within a single sample time, and four or more pulses occurring within a single sample time.

The modifications required to construct a circuit having 8 or more detectors, and corresponding modification of the binary representation required to represent the output of that circuit will be obvious to one skilled in the art.

Data obtained using the circuit shown in FIG. 6 is correlated using three independent correlators, as shown in FIG. 7. A first correlator 25 is used to correlate all data having a second identifier of ‘00’ (i.e. a single event occurring during a time interval, a second correlator 26 is used to correlate all data having a second identifier of ‘01’ (i.e. two or three events occurring during a time interval), and a third correlator 27 is used to correlate all data having a second identifier of ‘10’ (i.e. four events occurring during a time interval). Data is routed to an appropriate correlator 25-27 by a router 28. The router 28 may be a multiplexer or a system of logic gates, and is controlled by the output of the logical OR function and the logical AND functions shown in FIG. 6. Correlation of data in this manner is advantageous compared to conventional correlation of a data stream having a single identifier because it provides extra information regarding the pulse stream incident at the detectors, and in particular gives an indication of the distribution function of the pulse stream. It will be appreciated that the data may be modified, for example by truncation or non-linear representation before it is correlated (the modification should occur after the data has passed the multiplexer).

The three correlators illustrated in FIG. 7 may be replaced by a single correlator having interleaved channels. These interleaved channels will effectively provide three separate correlators.

Data formats having two separate identifiers may be used as described above, but data of this format cannot be correlated conventionally using a single correlator. In order to do correlate conventionally using a single correlator, the data must be converted into a format having a single identifier (i.e. the temporal separation of pulses).

A data stream having two separate identifiers may be converted to a representation having a single identifier by halving the duration of time represented by each bit of data. For example (001,0), (001,1), (010,0) is represented as 010, 001, 001, 100. In this example the first pulse 001 becomes 010; the second and third pulses which were represented together as 001,1 are now represented as separate consecutive pulses as 001, 001 (since each bit of data now represents a halved duration of time, the total represented time duration is unchanged); the fourth pulse 010,0 is represented as 100. This data may be passed to a conventional correlator, and correlated in the normal manner.

Data collected and correlated in this manner has twice the sensitivity of data that would have been obtained if a single detector had been used. The correlator is thus required to operate at twice the bandwidth that would have been required for a conventional detector arrangement.

The data reformatting described above may introduce bias into data, if it is applied to anything other than the most rapidly occurring pulses. For example, the data bit (010,1) represents 2 photons occurring simultaneously in time period 2, but would be reformatted as two photons occurring during successive time periods.

Where two pulses are recorded during a time period other than the first period following a preceding pulse, then a second reformatting method may be used. This involves representing the same pulse twice, such that the data stream (001,0,),(001,1),(010,1) becomes (010),(001),(001),(100),(100).

1. A method of pre-processing a signal comprising a series of temporally separated events, the method comprising modifying the temporal separation of the events prior to correlation of the signal.

2. A method according to claim 1, the wherein the temporal separation between consecutive events is monitored, and if the temporal separation exceeds a predetermined maximum value, the temporal separation is substituted with a predetermined lesser value.

3. A method according to claim 2, wherein the predetermined lesser value is the predetermined maximum value.

4. A method according to claim 2 or 3, wherein the predetermined maximum value corresponds to the maximum temporal separation that will provide a signal when the signal is correlated.

5. A pre-processing means for pre-processing a signal comprising a series of temporally separated events, the pre-processing means being arranged to modify the temporal separation of the events prior to correlation of the signal.

6. A pre-processing means according to claim 5, wherein the pre-processing means comprises a timing device which monitors the temporal separation between consecutive events, and where the temporal separation exceeds a predetermined maximum value, changes the temporal separation of the consecutive events to a predetermined lesser value.

7. A pre-processing means according to claim 6, further comprising a pulse generator which generates a series of temporally separated pulses in accordance with temporal separation values output from the timing device.

8. A pre-processing means according to claim 7, wherein a buffer is located between the timing device and the pulse generator.

9. A pre-processing means according to claim 8, wherein the buffer comprises a pair of buffers arranged such that temporal separation values may be written to a first buffer from the timing device whilst temporal separation values are simultaneously transferred from a second buffer to the pulse generator.

10. A method according to claim 1, the method comprising converting the temporal separation of the events into a non-linear form.

11. A method according to claim 10, wherein the non-linear form is arranged to represent progressively greater temporal separations with temporal separations that increase at a lesser rate.

12. A method according to claim 11, wherein the temporal separations are converted to the non-linear form in accordance with a predetermined sequence.

13. A method according to claim 12, wherein the predetermined sequence is a geometric or substantially geometric sequence.

14. A method according to claim 10, wherein the conversion to the non-linear form is arranged such that temporal separations of interest are given high resolution and temporal separations that are not of interest are given low resolution.

15. A method according to any of claims 1 to 4 or claims 10 to 14, wherein the method is used in a communications system, a receiver being arranged to separate a data signal and a test signal, the test signal being correlated with a stored test signal, and the resulting correlation output being used to adjust gain of a data signal amplifier.

16. A pre-processing means according to claim 5, wherein the pre-processing means further comprises a timing device which monitors the temporal separation between consecutive events, and converts the temporal separation of the events into a non-linear form.

17. A pre-processing means according to claim 16, further comprising a pulse generator which generates a series of temporally separated pulses in accordance with temporal separation values output from the timing device.

18. A pre-processing means according to claim 17, wherein a buffer is located between the timing device and the pulse generator.

19. A pre-processing means according to claim 18, wherein the buffer comprises a pair of buffers arranged such that temporal separation values may be written to a first buffer from the timing device whilst temporal separation values are simultaneously transferred from a second buffer to the pulse generator.

20. A method according to any of claims 5 to 9 or claims 16 to 19, wherein the pre-processing means is used in a communications system, a receiver being arranged to separate a data signal and a test signal, the test signal being correlated with a stored test signal, and the resulting correlation output being used to adjust gain of a data signal amplifier.

21. A method of pre-processing a signal comprising a series of temporally separated events, the method comprising converting the series of temporally separated events into a series of numbers, each number representing the temporal separation of two consecutive events.

22. A method according to claim 21, wherein the method further comprises writing the numbers directly into channels of a correlator.

23. A method according to claim 21 or claim 22, wherein the numbers are represented in binary and the numbers are converted to an alternative representation using a logical NOT function.

24. A method according to any of claims 21 to 23, further incorporating a method according to any of claims 1 to 4 or claims 10 to 15,

25. A pre-processing means for pre-processing a signal comprising a series of temporally separated events, comprising means for converting the series of temporally separated events into a set of numbers, each number representing the temporal separation of two consecutive events,.

26. A pre-processing means according to claim 25, further comprising means for writing the numbers directly into channels of a correlator.

27. A pre-processing means according to claim 25 or claim 26, wherein the numbers are represented in binary and the numbers are converted to an alternative representation using a logical NOT function.

28. A pre-processing means according to any of claims 25 to 27, further incorporating pre-processing means according to any of claims 5 to 9 or claims 16 to 19.

29. A method of detecting and representing a series of temporally separated events, the method comprising detecting the events using two detectors, and representing the series of events using a representation having two identifiers, a first identifier indicating whether events were detected simultaneously by the first and second detectors, and a second identifier indicating the time elapsed following a preceding event.

30. A method according to claim 29, wherein outputs from the two detectors are connected by a logical AND function, and the first identifier is determined using output from the logical AND function.

31. A method according to claim 29 or claim 30, wherein the outputs from the two detectors are connected together to provide a logical OR function, and the second identifier is determined using output from the logical OR function.

32. A method according to any of claims 29 to 31, wherein the events are detected using more than two detectors, and the first identifier is arranged to indicate how many events were detected simultaneously by the more than two detectors.

33. A method according to claim 32, wherein the number of detectors is chosen from the series 2ⁿ, where n is an integer.

34. A method according to claim 32 or claim 33, wherein outputs from selected pairs of detectors are connected using logical AND functions.

35. A method according to any of claims 29 to 34, wherein a router is arranged to direct a second identifier to one of a set of correlators, in accordance with the first identifier.

36. A method according to any of claims 29 to 35, wherein a router is arranged to direct a second identifier to a channel of a single correlator having interleaved channels, in accordance with the first identifier.

37. A method according to any of claims 29 to 34, wherein the representation is converted to a representation having a single identifier, by dividing the second identifier by a factor corresponding to the number of detectors, and generating multiple copies of the first identifier when the first identifier indicates that more than one event was detected simultaneously by the detectors, the number of copies corresponding to the number of simultaneous events.

38. An apparatus for detecting and representing a series of temporally separated events, the apparatus comprising two detectors for detecting events, and means for representing the series of events using a representation having two identifiers, a first identifier indicating whether events were detected simultaneously by the first and second detectors, and a second identifier indicating the time elapsed since a preceding event.

39. An apparatus according to claim 38, wherein outputs from the two detectors are connected by a logical AND function, and the first identifier is determined using output from the logical AND function.

40. An apparatus according to claim 38 or claim 39, wherein outputs from the two detectors are connected together to provide a logical OR function, and the second identifier is determined using output from the logical OR function.

41. An apparatus according to any of claims 38 to 40, wherein the apparatus comprises more than two detectors, and the first identifier is arranged to indicate how many events were detected simultaneously by the more than two detectors.

42. An apparatus according to claim 41, wherein the number of detectors is chosen from the series 2ⁿ, where n is an integer.

43. An apparatus according to claim 41 or claim 42, wherein outputs from selected pairs of detectors are connected using logical AND functions.

44. An apparatus according to any of claims 39 to 43, wherein a router is arranged to direct a second identifier to one of a set of correlators, in accordance with the first identifier.

45. A apparatus according to any of claims 39 to 43, wherein a router is arranged to direct a second identifier to a channel of a single correlator having interleaved channels, in accordance with the first identifier.

46. A apparatus according to any of claims 39 to 43, wherein the apparatus further comprises means for converting the representation to a representation having a single identifier, by dividing the second identifier by a factor corresponding to the number of detectors, and generating multiple copies of the first identifier when the first identifier indicates that more than one event was detected simultaneously by the detectors, the number of copies corresponding to the number of simultaneous events.

47. A method of pre-processing substantially as hereinbefore described with reference to the accompanying figures.

48. A pre-processing apparatus substantially as hereinbefore described with reference to the accompanying figures.
